(19) United States
(12) Patent Application Publication
(10) Pub. No.: US 2009/0321246 A1
(43) Pub. Date: Dec. 31, 2009

(54) METHOD OF FABRICATING AND APPARATUS OF FABRICATING TUNNEL MAGNETIC RESISTIVE ELEMENT

(75) Inventors: Koji Tsunekawa, Tokyo (JP); Yoshinori Nagamine, Tokyo (JP); Kazumasa Nishimura, Kawasaki-shi (JP); Franck Ernult, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/190,864

(22) Filed: Aug. 13, 2008

Related U.S. Application Data
(63) Continuation of application No. PCT/JP2008/061554, filed on Jun. 25, 2008.

(51) Int. Cl. C23C 14/34

(52) U.S. Cl. 204/192.2; 204/298.02

(57) ABSTRACT

A method and an apparatus of fabricating a tunnel magnetic resistive element which do not show much dispersion in RA and capable of obtaining a high MR ratio in a low RA are provided. The method of fabricating a tunnel magnetic resistive element includes a first ferromagnetic layer, a tunnel barrier layer made of metal oxide and a second ferromagnetic layer, wherein a step of making the tunnel barrier layer includes carrying out film formation of a first metal layer while doping oxygen on the first ferromagnetic layer, subsequently an oxidation process on the oxygen-doped first metal layer to make an oxide layer and film formation of a second metal layer on the oxide layer.

### CROSS-REFERENCES TO RELATED APPLICATIONS

This application is a continuation application of International Application No. PCT/JP2008/061554, filed on Jun. 25, 2008, the entire contents of which are incorporated by reference herein.

### TECHNICAL FIELD

The present invention relates to a magnetic reproducing head of a magnetic disk drive apparatus, a memory element of a magnetic random access memory and a magnetic sensor.

### BACKGROUND ART

A tunnel magnetic resistive element with crystalline MgO as a tunnel barrier layer obtains a huge MR ratio (percentage of magnetic resistive change) of 200% or more at the room temperature. Consequently, applications to a reproducing or read-out head of a magnetic disk drive apparatus, a memory element of magnetic random access memory (MRAM) and a magnetic sensor are being expected. In the case of a conventional tunnel magnetic resistive element obtained by adopting a tunnel barrier layer made of MgO, an RF magnetron sputtering method using an MgO sintering target is used for film formation of the MgO tunnel barrier layer (Patent Document 1, Non-Patent Documents 1 to 5). However, the MgO formation method by the RF magnetron sputtering using the MgO sintering target gives rise to a problem that dispersion is likely to occur in normalized tunnel resistive value (RA) and there is a risk to remarkably deteriorate the yield factor at the time of device fabrication.

In order to avoid such problems, alternative methods of forming the MgO tunnel barrier layer without using the MgO sintering target are known.

Tsann et al. have proposed a method of film formation of the MgO tunnel barrier layer in three steps of firstly carrying out film formation of a metal Mg layer, secondly stacking oxygen-doped metal Mg layers and thirdly bringing the laminated body into an oxidation process (Patent Document 2). Fu et al. have proposed a method of film formation of the MgO tunnel barrier layer in three steps of carrying out film formation of a first Mg layer, carrying out natural oxidation method on the first Mg layer to obtain an MgO layer and carrying out film formation of a second Mg layer on the MgO layer and a method of film formation in three steps of carrying out film formation of a first Mg layer, carrying out film formation of an MgO layer on the first Mg layer by reactive sputtering and carrying out film formation of a second Mg layer on the MgO layer (Patent Document 3).

Koh et al. have proposed a method of film formation of the MgO tunnel barrier layer in five steps of carrying out film formation of a first Mg layer, carrying out radical oxidation on the first Mg layer to obtain a first MgO layer, annealing the first MgO layer to provide (001) crystalline orientation, carrying out film formation of a second Mg layer on the first MgO layer and carrying out natural oxidation on the second Mg layer to obtain a second MgO layer. Koh et al. have also proposed a method of forming in five steps of carrying out film formation of a first Mg layer, carrying out radical oxidation on the first Mg layer to obtain a first MgO layer, carrying out film formation of a second Mg layer on the first MgO layer, carrying out radical oxidation on the second Mg layer to obtain a second MgO layer and film formation of a third Mg layer on the second MgO layer (Patent Document 4).

Miura et al. have proposed a method of film formation of the MgO tunnel barrier layer in four steps of carrying out film formation of a first Mg layer, carrying out natural oxidation on the first Mg layer, carrying out film formation of a second Mg layer on the first Mg layer and carrying out natural oxidation on the second Mg layer at oxygen pressure lower than at the time of oxidizing the first Mg layer (Patent Document 5).

Dave et al. have proposed a method of film formation of the MgO tunnel barrier layer consisting of four kinds of methods, that is, a method of bringing metal Mg into plasma oxidation, a method of bringing metal Mg into radical oxidation, reactive sputtering with proportion of Ar to oxygen being 5:3 and RF sputtering with an MgO sintering target (non-Patent Document 6). Oh et al. have also proposed a method of bringing metal Mg into radical oxidation as a method of film formation of the MgO tunnel barrier layer (non-Patent Document 7).

### Patent Document 1: Japanese Patent Application Laid-Open No. 2006-080116

Patent Document 2: U.S. Pat. No. 6,841,395

### Patent Document 3: Japanese Patent Application Laid-Open No. 2007-142424

### Patent Document 4: Japanese Patent Application Laid-Open No. 2007-173843

### Patent Document 5: Japanese Patent Application Laid-Open No. 2007-305768

### Non-Patent Document 1: D. D. Djayaprawira et al., “Applied Physics Letter”, 86, 092502 (2005)

Non-Patent Document 2: J. Hayakawa et al. “Japanese Journal of Applied Physics”, L587, 44 (2005)
Non-Patent Document 3: K. Tsunekawa et al. “Applied Physics Letter”, 87, 072503 (2005)
Non-Patent Document 4: S. Ikeda et al. “Japanese Journal of Applied Physics”, L1442, 44 (2005)
Non-Patent Documenet 5: Y. Nagamine et al. “Applied Physics Letter”, 89, 162507 (2006)
Non-Patent Document 6: R. W. Dave et al. “IEEE Transactions on Magnetics”, 42, 1935 (2006)
Non-Patent Document 7: S. C. Oh et al. “IEEE Transactions on Magnetics”, 42, 2642 (2006)

In an attempt to form an MgO tunnel barrier layer just by oxidizing metal Mg, it is difficult to obtain RA less than or equal to several 100 Ω·μm² as introduced in the non-Patent Document 6 and the non-Patent Document 7. The reason hereof is considered that, metal Mg is exposed to the oxygen atmosphere and then passivation film is formed on its surface so that further deeper oxidation hardly becomes likely to progress.

Therefore, a method of solving the problem described above by repeating film formation and oxidation of metal Mg twice is proposed in the Patent Document 4 and the Patent Document 5. However, the method of repeating film formation and oxidation of metal Mg twice gives rise to a problem that shuttling between a film formation chamber and an oxidation processing chamber remarkably decreases throughput of production. Or a method of providing two chambers of a film formation chamber and an oxidation processing chamber for metal Mg each in order to avoid decrease of throughput due to repeated conveyance can be considered. However, that case gives rise to a problem of increase of production costs for devices due to increase of the cost for apparatuses and increase of the area for installation and the like.

The methods in the Patent Document 2 and the Patent Document 3 require a smaller number of steps comparatively so that the problems on the throughput and the production cost are resolved. However, with the MR ratio in the low RA region being not more than 40%, performance of the tunnel magnetic resistive element with a MgO tunnel barrier layer is not sufficient. In addition, due to unavailability of any example on dispersion of the RA that affects the yield factor significantly, it is uncertain whether or not the process is appropriate for production.

An object of the present invention is to provide a method and an apparatus of fabricating a tunnel magnetic resistive element requiring comparatively few numbers of steps, provided with excellent property in uniformity of RA and capable of obtaining a high MR ratio at a low RA.

### DETAILED DESCRIPTION OF EMBODIMENTS

The present invention solved the problems described above with a method of fabricating a tunnel magnetic resistive element including a first ferromagnetic layer, a tunnel barrier layer made of metal oxide and a second ferromagnetic layer, wherein a step of making the tunnel barrier layer includes carrying out film formation of a first metal layer on the first ferromagnetic layer, using oxygen doping, subsequently an oxidation process on the oxygen-doped first metal layer to make an oxide layer and film formation of a second metal layer on the oxide layer.

According to the present invention, a method and an apparatus of fabricating a tunnel magnetic resistive element which does not show much dispersion in RA and capable of obtaining a high MR ratio in a low RA can be provided.

### BRIEF DESCRIPTION OF THE DRAWINGS

FIG. 1 is a plan view schematically illustrating a configuration of a sputtering apparatus usable for fabrication of a tunnel magnetic resistive element of the present invention;

FIG. 2 is a schematic sectional diagram of a tunnel magnetic resistive element related to the present embodiment;

FIG. 3 is a film block diagram of a tunnel magnetic resistive element produced with the fabrication method and the fabrication apparatus of the present invention;

FIG. 4 is a flow chart to form a tunnel barrier layer according to the present example;

FIG. 5A and FIG. 5B are graphs where MR ratio and RA of the present tunnel magnetic resistive element are plotted against oxidation time;

FIG. 6 is a flow chart for forming a tunnel barrier layer in the case where oxygen gas is not used in the initial and final periods of film formation at the occasion of oxygen doping at the time of film formation of the first metal layer;

FIG. 7 is a schematic time chart of Power supplied at the time of film formation of a metal Mg layer, shutter opening and closure, Ar gas introduction and oxygen gas introduction;

FIG. 8 is a graph illustrating relation between RA and MR ratio of a tunnel magnetic resistive element produced with the present invention method;

FIG. 9 is a graph illustrating distribution of RA inside the substrate surface for the case of radical oxidation only with an oxidation time of 100 seconds in a tunnel magnetic resistive element related to Example 3;

FIG. 10 is a graph illustrating dispersion of RA between substrates for the case of radical oxidation only with an oxidation time of 20 seconds in the case of a tunnel magnetic resistive element related to Example 4; and

FIG. 11 is a graph illustrating MR ratio as a function of the thickness of the second metal Mg layer in a magnetic tunnel element of Example 1.

### PREFERRED EMBODIMENTS

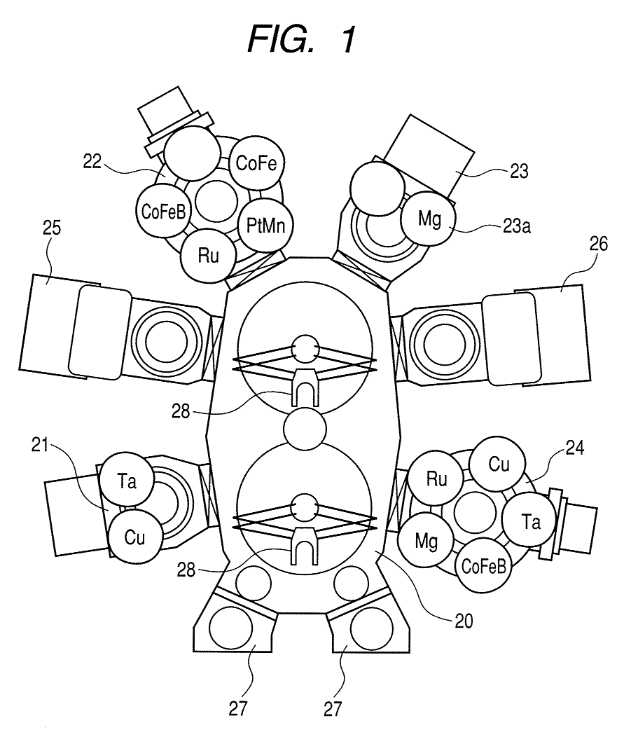

Embodiments of the present invention will be described with the drawings. FIG. 1 is a plan view schematically illustrating a configuration of a sputtering apparatus usable for fabrication of a tunnel magnetic resistive element of the present invention. Such an apparatus is configured by a vacuum transfer chamber 20 where two robots 28 for conveying substrates are mounted, sputtering chambers 21 to 24 connected to the vacuum transfer chamber 20, substrate pre-processing chamber 25, oxidation processing chamber 26 and a load lock chamber 27. All chambers except the load lock chamber 27 are vacuum chambers of not more than 2×10⁻⁶ Pa. A substrate moves between the respective vacuum chambers in the vacuum using a vacuum conveyance robot 28.

A substrate for forming spin-valve type tunnel magnetic resistive thin film is arranged in the load lock chamber 27 which is initially set at the atmosphere pressure and is conveyed to a desired vacuum chamber with the vacuum conveyance robot 28 after the load lock chamber 27 is pumped down to attain the vacuum.

As an example, a case of fabricating a spin valve type—magnetic tunnel junction of a bottom type including a synthetic antiferromagnet layer as a magnetization fixed layer produced in an example to be described later will be described. In the present specification, a synthetic antiferromagnet layer (SAF) stands for any stack including two ferromagnetic layers separated by a non-magnetic spacer and with their magnetizations anti-parallel to each other. These magnetizations for two ferromagnetic layers can be the same or different. FIG. 2 is a sectional schematic view of a tunnel magnetic resistive element related to the present embodiment.

Specific configurations of the respective layers will be described with reference to FIG. 2. A lower part electrode layer 2 has laminated structure consisting of Ta (5 nm), CuN (20 nm), Ta (3 nm), CuN (20 nm) and Ta (3 nm). An antiferromagnetic layer 3 is made of PtMn (15 nm); a magnetization fixed layer 4 is a synthetic antiferromagnet layer consisting of CoFe (2.5 nm), Ru (0.85 nm) and CoFeB (3 nm); and CoFeB of the layer 4b corresponds to the first ferromagnetic layer mentioned in chain 1 and subsequents. The tunnel barrier layer 6 is MgO (1.5 nm). Magnetization free layer 7 is CoFeB (3 nm) and corresponds to the second ferromagnetic layer mentioned in chain 1 and subsequents. As a protection layer 8, laminated structure of Ta (8 nm), Cu (30 nm), Ta (5 nm) and Ru (7 nm) is used. Here, film thicknesses are indicated inside the brackets.

The PtMn layer is formed to attain the Pt content of 47 to 51 (atomic %) by adjusting composition of the sputtering target and film formation conditions (gaseous species, gas pressure and input power supply) so that the PtMn layer is ordered by annealing to induce antiferromagnetic properties.

In order to carry out film formation of a film configuration as described above efficiently, sputtering targets are arranged in each sputtering chamber as follows. Respectively as sputtering targets 21a to 21b and 22a to 22d and 23a, Ta (tantalum) and Cu (copper) are arranged in the sputtering chamber 21; CO₇₀Fe₃₀ (cobalt-iron), PtMn (platinum-manganese), Ru (ruthenium) and CO₆₀Fe₂₀B₂₀ (cobalt-iron-boron) are arranged in the sputtering chamber 22; Mg is arranged in the sputtering chamber 23. In addition, Ta, CO₆₀Fe₂₀B₂₀, Mg, Ru and Cu are arranged in the sputtering chamber 24 as sputtering targets 24a to 24e.

In the present invention, spin valve type—magnetic tunnel junctions including a synthetic antiferromagnet structure and being the most complicated film configuration in the present invention are formed as follows. At first, the substrate 1 is conveyed to the substrate pre-processing chamber 25 and approximately 2 nm thickness on the surface layer contaminated in the atmosphere is physically removed by reverse sputter etching. Thereafter, the substrate 1 is conveyed to the sputtering chamber 21 to carry out film formation of the lower part electrode layer 2 consisting of laminated structure of Ta/CuN/Ta/CuN/Ta. At that time, at the time of film formation of CuN, a Cu target is used. A tiny amount of nitrogen is added besides Ar as sputtering gas to, thereby, form CuN. Thereafter, the substrate is moved to the sputtering chamber 22 to carry out film formation of an antiferromagnetic layer 3 consisting of PtMn/CoFe/Ru and a magnetization fixed layer 4 (first ferromagnetic layer) made of CoFeB. Here, instead of PtMn as the antiferromagnetic layer 3, IrMn (iridium-manganese) can be used. In that case, an Ru layer is preferably used as a buffer layer 9 of the IrMn layer. In such a case, the film to undergo film formation at the sputtering chamber 22 will be Ru/IrMn/CoFe/Ru/CoFeB.

Next, a method of forming the tunnel barrier layer will be described. After formation of the films up to CoFeB, the substrate 1 is moved to the sputtering chamber 23 so that metal Mg undergoes film formation with oxygen doping. As an example of a method of oxygen doping, Ar and oxygen are used as sputtering gas. Here, the oxygen gas to be mixed in is preferably not more than 30% of the sputtering gas. The reason hereof is that surface oxidation of the Mg target is suppressed.

The vacuum chamber is provided with respectively individual gas introducing entrance. Gas is introduced while individually controlling flow of Ar and oxygen. The timing for introducing oxygen gas at the time of oxygen doping does not necessarily have to be the same as the timing of introducing Ar being the sputtering gas, but can be later than the timing of introducing Ar or earlier than the timing of stopping Ar supply.

Next, the substrate 1 is moved to the oxidation processing chamber 26 to undergo an oxidation process. As a method of the oxidation process, any of natural oxidation and radical oxidation can be used. In the case of the natural oxidation, the pressure of the oxygen atmosphere is maintained at 0.01 to 10 Torr and the substrate is left for a predetermined time. In the case of radical oxidation, oxygen plasma is caused to occur by applying high frequency to the electrode in the oxygen atmosphere. The substrate is placed below a shower plate in which a plurality of holes with length of around 10 mm and diameter of around 1 mm are opened and through which particles (radical oxygen species and oxygen) besides charged particles in the plasma can flow and irradiate the substrate.

Subsequently, the substrate 1 is moved to the sputtering chamber 24 to carry out film formation of Mg/CoFeB/Ta/Cu/Ta/Ru. Mg film thickness is preferably not less than 0.1 nm and not more than 0.6 nm. Thereby, as described later with FIG. 11, MR ratio of more than or equal to 100% can appear.

Hereafter, the produced magnetic tunnel junctions are placed into an annealing furnace in which a magnetic field is applied. While a unidirectional parallel magnetic field with intensity of more than or equal to 8 kOe is applied, an anneal process is carried out at a desired temperature and for desired time in the vacuum. Experimentally, not less than 250° C. and not more than 360° C. is adopted. In the case of a low temperature, long time of not less than 5 hours is preferable and in the case of a high temperature, short time of not more than 2 hours is preferable.

Here, the above described embodiment adopted Ar (argon) as the principal component for the sputtering gas, but, will not be limited hereto. For example, sputtering gas with at least one of He (helium), Ne (neon), Kr (krypton) and Xe (xenon) as the principal component can be used.

### EXAMPLES

Next, examples of the present invention will be described with the drawings.

### Example 1

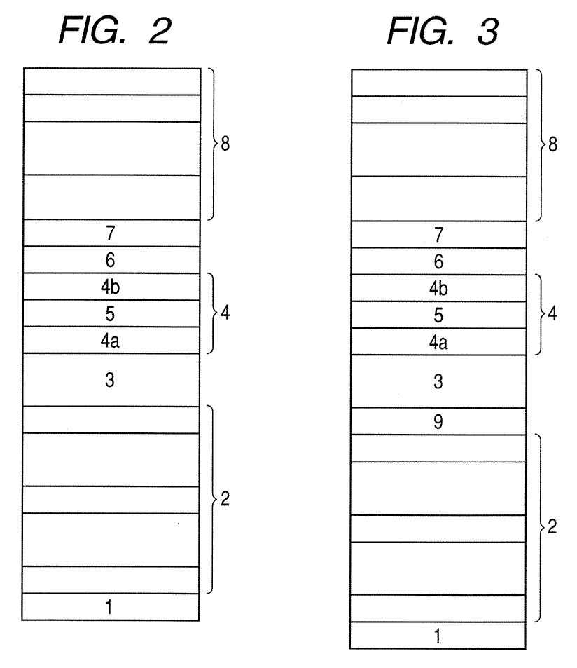

FIG. 3 is a film configuration diagram of a tunnel magnetic resistive element produced with a fabrication method and a fabrication apparatus related to the present invention. IrMn with thickness of 7 nm is used as antiferromagnetic layer 3. A Ru layer of 5 nm is used as its underlying layer 9. Otherwise, the film configuration is the same as that of FIG. 2.

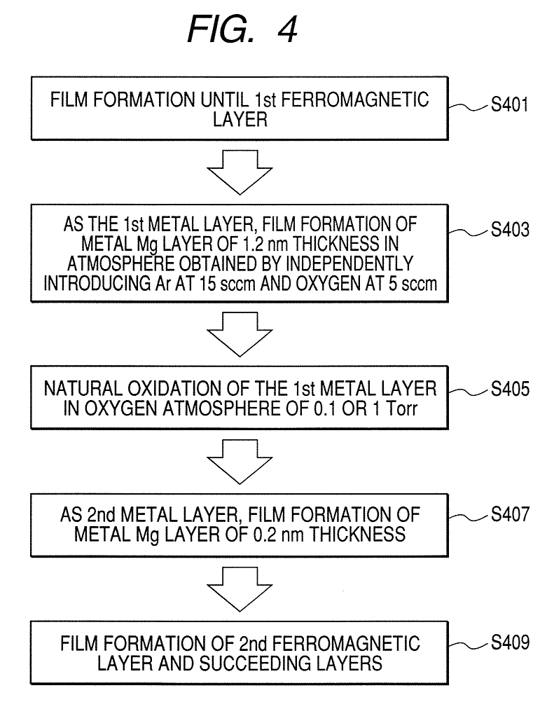

With reference to FIG. 4, a forming method of a tunnel barrier layer related to the present example will be described. FIG. 4 is a flow chart of film formation of a tunnel barrier layer according to the present example. In a step S401, film formation was carried out until a first ferromagnetic layer is formed as described in the above embodiment. In a step S403, on a CoFeB layer to become the first ferromagnetic layer, film formation of metal Mg of 1.2 nm was carried out in the atmosphere obtained by independently introducing Ar gas at 15 sccm and oxygen at 5 sccm (the mixed oxygen concentration is 25%). Subsequently, in a step S405, natural oxidation was carried out for 60 to 600 seconds in the oxygen atmosphere of 0.1 Torr or 1 Torr in an oxygen treatment chamber. Lastly, in a step S407, film formation of metal Mg layer of 0.2 nm was carried out in the atmosphere obtained by introducing only Ar gas at 15 sccm. Thereafter, in a step S409, film formation of succeeding layers of CoFeB/Ta/Cu/Ta/Ru was carried out to finalize film formation of a tunnel magnetic resistive element.

The present tunnel magnetic resistive element is put into an annealing furnace in a magnetic field to carry out an anneal process in a magnetic field of 1 T at 360° C. for 2 hours under vacuum.

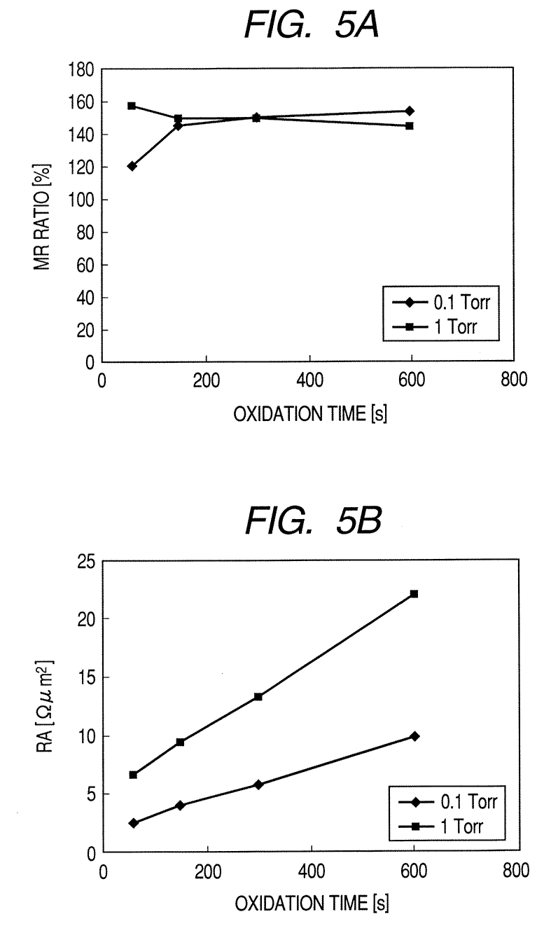

FIG. 5A and FIG. 5B are graphs plotting MR ratio and RA against oxidation time for the present tunnel magnetic resistive element. As illustrated in FIG. 5A, MR ratio in excess of 100% is obtained under any oxidation condition. As illustrated in FIG. 5B, for RA, under any oxidation condition, as oxidation time increases, RA increases and, RA at low-pressure condition of 0.1 Torr is approximately the half of the value obtained under the high-pressure condition of 1 Torr. The lowest RA is obtained at the time of carrying out the oxidation process under the condition of 0.1 Torr for 60 seconds. The MR ratio of 121% is attained for RA of 2.6 Ωμm².

Here, the MR ratio and the RA was measured by Current-In-Plane-Tunneling (CIPT) method with 12-terminal probe. The measurement principle of the CIPT method is described in D. C. Worledge and P. L. Trouilloud, “Applied Physics Letters”, 83 (2003), 84-86.

### Example 2

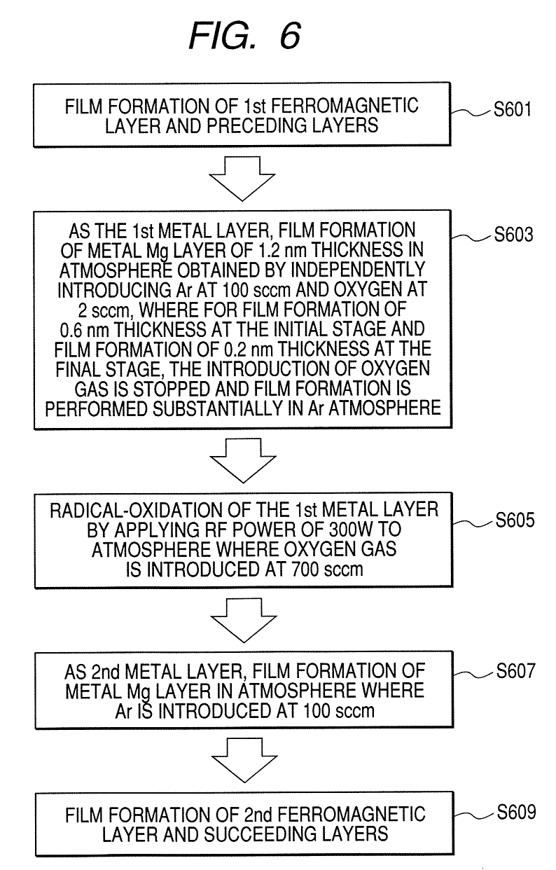

FIG. 6 illustrates a flow chart for forming a tunnel barrier layer in the case of stopping mixture of oxygen gas in the initial period and at the end of film formation at the occasion of oxygen doping at the time of film formation of the first metal layer. At that time, radical oxidation was used as a method of oxidizing the first metal layer. The film configuration in FIG. 2 was adopted for the film configuration of the tunnel magnetic resistive element.

With reference to FIG. 6, the flow of forming the tunnel barrier layer will be described below. In a step S601, film formation of up to the first ferromagnetic layer was carried out as described in the above embodiment. In a step S603, through the following three steps, film formation of the first metal layer was carried out on the first ferromagnetic layer. That is, at the initial stage of film formation of the first metal layer, film formation of the first metal layer was carried out in the Ar gas atmosphere without introducing oxygen gas (a lower part layer of the first metal layer). At the middle stage of film formation, film formation of the first metal layer was carried out in the atmosphere subjected to introduction of Ar gas and oxygen gas (a middle layer of the first metal layer). Moreover, at the final stage of film formation, film formation of the first metal layer was carried out in the Ar gas atmosphere without introducing oxygen gas (an upper part layer of the first metal layer). Thus, it is possible to suppress the case where the first ferromagnetic layer and the second ferromagnetic layer are partially oxidized.

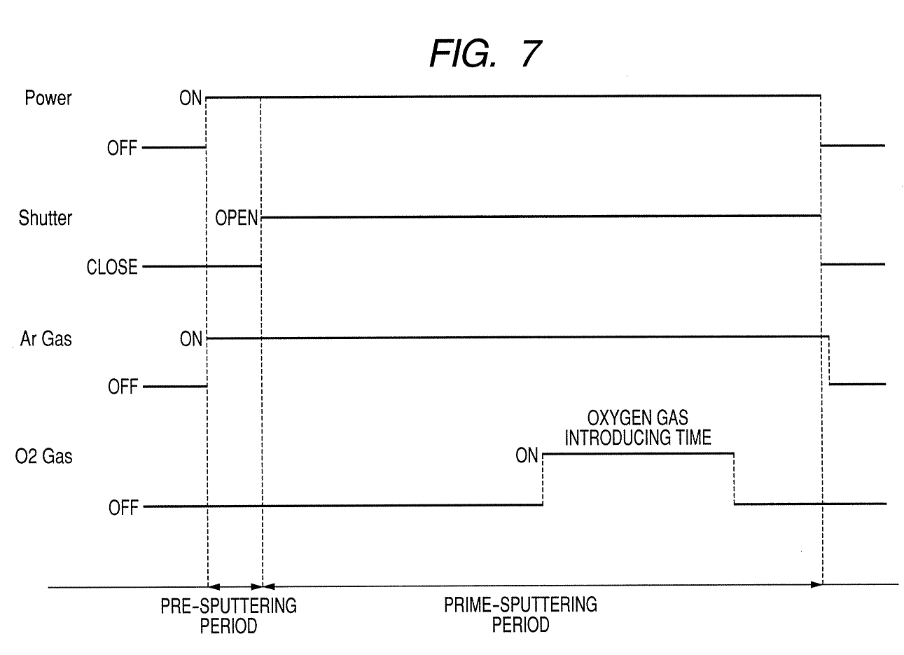

The step S603 described above will be described in further detail as follows. At first, film formation of metal Mg (first metal layer) of 1.2 nm is carried out on a CoFeB layer to become the first ferromagnetic layer in the sputtering chamber 23. FIG. 7 is a schematic time chart illustrating Power supplied at the time of film formation of this metal Mg layer of 1.2 nm, shutter opening and closure, Ar gas introduction and oxygen gas introduction. At first, application of Power to the cathode with an Mg target and introduction of Ar gas to inside a vacuum chamber are carried out nearly concurrently to generate plasma. The power to be applied is DC 50 W and flow rate of the Ar gas to be introduced is 100 sccm. During this pre-sputtering period, a shutter arranged between the target and the substrate is closed. Therefore, no film is deposited on the substrate.

Next, the shutter is opened so that film formation starts. When film thickness reaches 0.6 nm (corresponding to a lower part layer of the first metal layer), oxygen gas at 5 sccm (oxygen concentration=4.76%) is introduced so that the Mg layer undergoes doping with a tiny amount of oxygen. When the film thickness of the Mg layer reaches 1.0 nm (corresponding to a middle layer of the first metal layer), introduction of oxygen is halted. Continuously, film formation of the remaining Mg layer of 0.2 nm is carried out in the Ar atmosphere (corresponding to an upper part layer of the first metal layer) so that film formation of the first metal layer of 1.2 nm is finalized. During the above process, gas exhaust from the chamber is continuously conducted with the gas introduction. Accordingly, after the introduction of oxygen gas has been halted, the amount of oxygen is gradually decreased in the atmosphere so that the atmosphere is substantially in Ar atmosphere.

Here, in the present example, film formation of the first metal layer was carried out in the Ar atmosphere at the initial stage of the film formation and at the final stage of the film formation of the first metal layer without introducing oxygen and, however, does not necessarily have to be carried out in the both stages. A method of film formation of the first metal layer in the Ar atmosphere without introducing oxygen only at any one of the film forming stages can be adopted.

Next, in a step S605, the substrate is moved to the oxidation processing chamber 26 to undergo radical oxidation. At the time of radical oxidation, oxygen gas at 700 sccm was introduced to inside the vacuum chamber and RF power of 300 W was applied to electrodes. The oxidation time was 10 seconds.

At last, in a step S607, the substrate is moved to the sputtering chamber 24 to carry out film formation of metal Mg (corresponding to the second metal layer) of 0.3 nm. Subsequently, in a step S609, film formation of the second ferromagnetic layer and succeeding layers was carried out as described in the above embodiment.

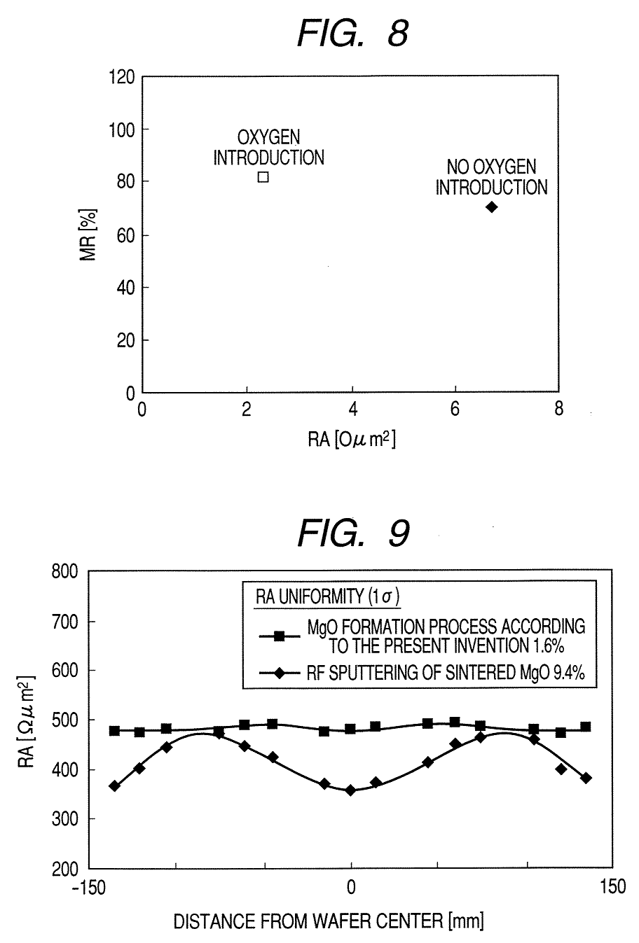

FIG. 8 is a graph illustrating relation between RA and MR ratio of a tunnel magnetic resistive element produced with the present invention method. For the purpose of comparison, data in the case where no oxygen is introduced at the time of film formation of the first metal Mg layer were plotted. By doping oxygen into the first metal Mg layer through an introduction of oxygen in forming the first metal Mg layer, a high MR ratio of 86% at low RA of 2.5 Ωμm² was attainable.

### Example 3

FIG. 9 is a graph illustrating distribution of RA inside the substrate surface at the occasion of radical oxidation only with an oxidation time of 100 seconds in a tunnel magnetic resistive element with the same film configuration as the tunnel magnetic resistive element obtained through the same method of forming the MgO tunnel barrier as those used for Example 2. The abscissa axis is for distance from the center of the wafer having a diameter of 300 mm. For the purpose of comparison, the graph also shows RA distribution of a tunnel magnetic resistive element with an MgO tunnel barrier having been formed by RF sputtering directly from an MgO sintering target. According hereto, the RA distribution of the tunnel magnetic resistive element formed by the method of the present invention is 1.6% being a result apparently better than the RA distribution of 9.4% of the method by RF sputtering on the MgO sintering target.

### Example 4

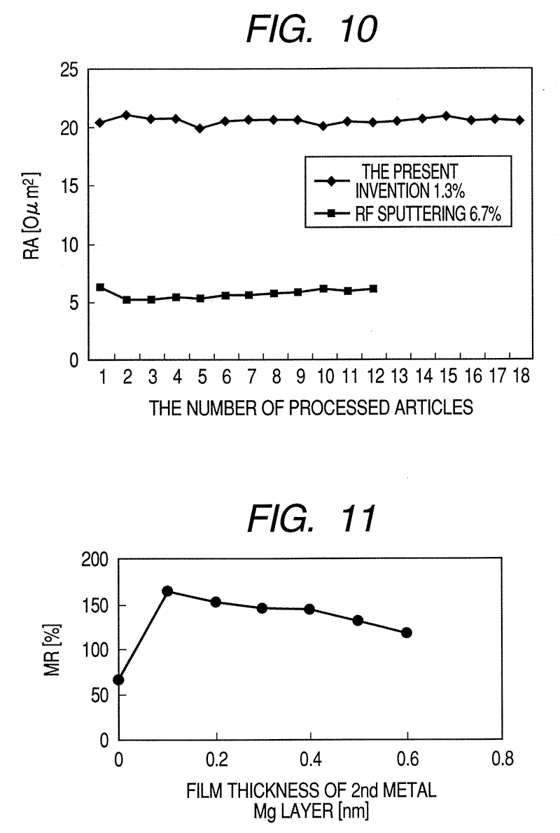

FIG. 10 is also a graph illustrating dispersion of RA between substrates at the occasion of radical oxidation only with an oxidation time of 20 seconds in the case of a tunnel magnetic resistive element with the same film configuration as the tunnel magnetic resistive element obtained through the same method of forming the MgO tunnel barrier as those used for Example 2. The abscissa axis shows the number of substrates having undergone a continuous process. For the purpose of comparison, the graph also runs RA dispersion of a tunnel magnetic resistive element with an MgO tunnel barrier having been formed by RF sputtering directly from an MgO sintering target. According hereto, the inter-substrate RA dispersion of the tunnel magnetic resistive element formed by the method of the present invention is 1.3%, apparently better than the RA dispersion of 6.7% of the method using RF sputtering on the MgO sintering target.

### Example 5

FIG. 11 is a graph illustrating MR ratio as a function of the film thickness of the second metal Mg layer in a magnetic tunnel element of Example 1. The MR ratio apparently increases remarkably by film formation of the second metal Mg layer. Based on the present result, film thickness of the metal Mg layer to undergo film formation as the second metal layer is preferably not less than 0.1 nm and not more than 0.6 nm. Thus, it is possible to realize the MR ratio of not less than 100%.

1. A method of fabricating a tunnel magnetic resistive element including a first ferromagnetic layer, a tunnel barrier layer made of metal oxide and a second ferromagnetic layer, wherein a step of making the tunnel barrier layer includes a formation process of a first metal layer on the first ferromagnetic layer, using oxygen doping, subsequently an oxidation process on the oxygen-doped first metal layer to make an oxide layer and a formation process of a second metal layer on the oxide layer.

2. The method of fabricating a tunnel magnetic resistive element according to claim 1, characterized in that the first and the second metal layers are made of Mg (magnesium).

3. The method of fabricating a tunnel magnetic resistive element according to claim 1, characterized in that the method of film formation of the first and the second metal layers is a sputtering method with at least one of He (helium), Ne (neon), Ar (argon), Kr (krypton) and Xe (xenon) as the principal component of sputtering gas.

4. The method of fabricating a tunnel magnetic resistive element according to claim 1, characterized in that oxygen gas of not more than 30% is mixed in the sputtering gas as a method of oxygen doping during film formation of the first metal layer.

5. The method of fabricating a tunnel magnetic resistive element according to claim 1, characterized in that an inlet of sputtering gas and an inlet of oxygen gas are individually provided to control flow of the sputtering gas and flow of the oxygen gas independently as a method of oxygen doping during film formation of the first metal layer.

6. The method of fabricating a tunnel magnetic resistive element according to claim 5, characterized in that at the occasion of oxygen doping during film formation of the first metal layer, oxygen gas is not introduced at starting and conclusion of film formation but is introduced only in the midst of film formation and,
whereby, such a state is realized that a middle layer, which is formed by introducing oxygen gas in the first metal layer, is provided with oxygen concentration higher than a lower part layer and an upper part layer of the first metal layer which are formed without forming oxygen gas.

7. The method of fabricating a tunnel magnetic resistive element according to claim 1, characterized in that a method of oxidizing the oxygen-doped first metal layer is exposure to an atmosphere of oxygen at pressure within a range of 0.01 to 10 Torr.

8. The method of fabricating a tunnel magnetic resistive element according to claim 1, characterized in that a method of oxidizing the oxygen-doped first metal layer is radical oxidation with radical oxygen species.

9. The method of fabricating a tunnel magnetic resistive element according to claim 1, characterized in that the second metal layer is made of Mg and its film thickness is not less than 0.1 nm and not more than 0.6 nm.

10. An apparatus of fabricating a tunnel magnetic resistive element realizing the fabrication method according to claim 1, characterized by including:
a vacuum transfer chamber comprising a substrate handling mechanism;
a first sputtering film formation chamber connected to the vacuum transfer chamber through a gate valve and capable of sputtering film formation of at least the first ferromagnetic layer;
a second sputtering film formation chamber connected to the vacuum transfer chamber through a gate valve and capable of sputtering film formation of the first metal layer in an oxygen mixed gas atmosphere to form an oxygen-doped metal layer;
an oxidation processing chamber connected to the transfer chamber through a gate valve and capable of oxidation process of the oxygen-doped metal layer to make an oxide layer; and
a third sputtering film formation chamber connected to the conveyance chamber through a gate valve and capable of sputtering film formation of at least the second metal layer and the second ferromagnetic layer.
